(19) United States
(12) Patent Application Publication
(10) Pub. No.: US 2007/0163496 A1
(43) Pub. Date: Jul. 19, 2007

(54) CHEMICAL VAPOR DEPOSITION APPARATUS HAVING A REACTION CHAMBER CONDITION DETECTION FUNCTION AND A DETECTION METHOD THEREOF

(76) Inventor: Chien-Hsing Lai, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/693,736

(22) Filed: Mar. 30, 2007

Related U.S. Application Data
(62) Division of application No. 10/904,878, filed on Dec. 2, 2004.

(51) Int. Cl. C23C 16/00; B05C 11/00

(52) U.S. Cl. 118/663; 427/248.1; 118/715

(57) ABSTRACT

A chemical vapor deposition apparatus includes a heating holder positioned in a reaction chamber, a shower head positioned substantially parallel to and above the heating holder, and a reaction chamber condition detector electrically connected to the heating holder and the shower head. The heating holder and the shower head form a capacitor, and the reaction chamber condition detector includes a resistor connected to the capacitor in series so as to form an RC circuit.

### CROSS REFERENCE TO RELATED APPLICATIONS

This application is a divisional of application Ser. No. 10/904,878 filed Dec. 2, 2004.

### BACKGROUND OF THE INVENTION

1. Field of the Invention

The present invention relates to a chemical vapor deposition apparatus having a reaction chamber condition detector and a detection method thereof, and more particularly, to a chemical vapor deposition apparatus which determines the reaction chamber condition by detecting the capacitance and a detection method thereof.

2. Description of the Prior Art

A typical chemical vapor deposition (CVD) process is a thin film technique which deposits a thin film onto a wafer in a chemical manner. Currently, CVD processing has become one of the most essential thin film techniques in semiconductor fabrication.

Please refer to FIG. 1, which is a schematic diagram of a conventional CVD apparatus 10. As shown in FIG. 1, the CVD apparatus 10 includes a reaction chamber 12, a heating holder 14 positioned in the reaction chamber 12, and a shower head 16 positioned parallel to and over the heating holder 14 in the reaction chamber 12. The heating holder 14, used to support a wafer (not shown), further includes a heating plate 18 disposed on the bottom surface of the heating holder 18 to provide a heating function, so that the reaction temperature of the wafer can be well controlled. The heating holder 14 is supported by a supporting shaft 20. In addition, the CVD apparatus 10 further includes a plurality of pins 22 and a plate 24 under the heating holder 14. The plate 24 is driven by a hoist shaft 26, and therefore can move upwardly so as to hoist the wafer with the pins 22. This prevents the wafer from cracking due to a high temperature difference.

While performing a CVD process, the reaction gases are let into the shower head 16 via at least a gas inlet 28. The reaction gases are then ejected through a plurality of openings 30, spread all over the reaction chamber 12, and deposited onto the wafer. Normally, the shower head 16 includes two disk structures, and at least an O-ring (not shown) disposed between the disk structures for preventing gas leakage from the seam between the two disk structures.

After operation, however, the bottom surface of the shower head 16 or the top surface of the heating holder 14 may have particles adhered thereto due to unexpected reasons, e.g. O-ring deformations. These particles can cause a reaction chamber condition shift, e.g. a gap change between the heating holder 14 and the shower head 16, and influence the yield of the CVD process. In the prior art, the reaction chamber condition is determined by inspecting a wafer having undergone the CVD process. Once poor quality of the thin film deposited onto the wafer is attributed to the reaction chamber condition, the CVD apparatus 10 will then be shut down for further inspection. Therefore, the conventional detection method is ineffective, and causes waste of product.

### SUMMARY OF THE INVENTION

It is therefore a primary object of the claimed invention to provide a chemical vapor deposition apparatus having a reaction chamber condition detector and a detection method thereof to overcome the aforementioned problem.

According to a preferred embodiment of the claimed invention, a CVD apparatus is disclosed. The CVD apparatus includes a heating holder positioned in a reaction chamber, a shower head positioned substantially parallel to and above the heating holder, and a chamber condition detector electrically connected to the heating holder and the shower head. The heating holder and the shower head form a capacitor, and the reaction chamber condition detector includes a resistor connected to the capacitor in series so as to form an RC circuit.

The present invention also discloses a detection method in accordance with the aforementioned CVD apparatus. First, the heating holder and the shower head are adjusted to a detection position. Then, the reaction chamber condition detector is utilized to charge and to discharge the capacitor, and a detected value is calculated. Finally, the detected value is compared with an ideal value, if the detected value substantially equals to the ideal value, the reaction chamber condition is normal, if the detected value differs from the ideal value, the reaction chamber condition is shifted.

Since the reaction chamber condition influences the capacitance of the capacitor formed by the heating holder and the shower head, the present invention is capable of detecting the reaction chamber condition by detecting capacitance variations of the capacitor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional CVD apparatus.

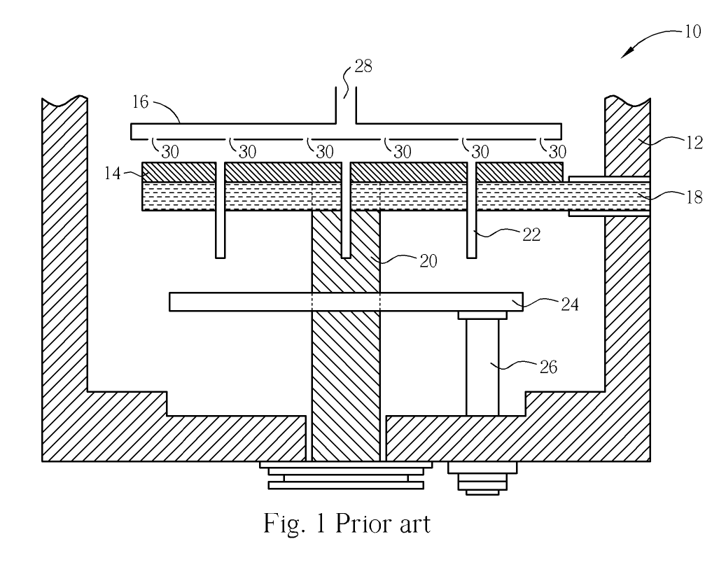

FIG. 2 is a schematic diagram of a CVD apparatus of a preferred embodiment of the present invention.

FIG. 3 is an equivalent circuit diagram of the CVD apparatus shown in FIG. 2.

FIG. 4 is a flowchart of the method of detecting a reaction chamber condition of a CVD apparatus according to the present invention.

FIG. 5 is a graph of t and

$$log [ \frac{ɛ}{ɛ - Vc} ] .$$

FIG. 6 is a graph of t and

$$log [ \frac{ɛ}{Vc} ] .$$

### DETAILED DESCRIPTION

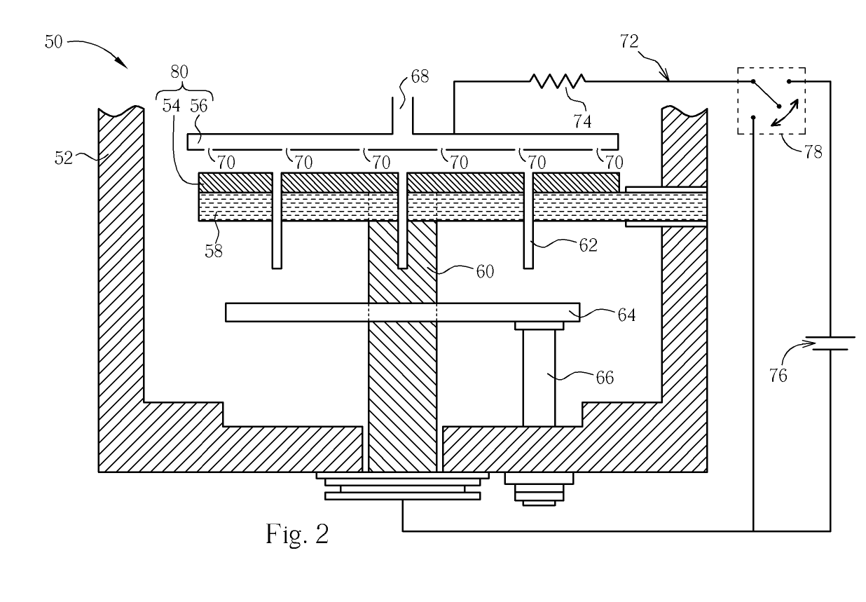

Please refer to FIG. 2, which is a schematic diagram of a CVD apparatus 50 of a preferred embodiment of the present invention. As shown in FIG. 2, the CVD apparatus 50 includes a reaction chamber 52, a heating holder 54 positioned in the reaction chamber 52, and a shower head 56 positioned substantially parallel to and above the heating holder 54 in the reaction chamber 52. The heating holder 54, used to support a wafer, further includes a heating plate 58 disposed on the bottom surface of the heating holder 58 to provide a heating function, so that the reaction temperature of the wafer can be well controlled. The heating holder 54 is supported by a supporting shaft 60. In addition, the CVD apparatus 50 further includes a plurality of pins 62 and a plate 64 under the heating holder 54. The plate 64 is driven by a hoist shaft 66, and therefore can move upwardly so as to hoist the wafer with the pins 62. This prevents the wafer from cracking due to a high temperature difference. The shower head 56 further includes a gas inlet 68 positioned on the top surface which allows the reaction gases to be introduced, and a plurality of openings 70 positioned on the bottom surface to eject the reaction gases so that the reaction gases are deposited onto the wafer.

The CVD apparatus 50 further includes a reaction chamber condition detector 72 electrically connected to the heating holder 54 and the shower head 56. The reaction chamber condition detector 72 includes a resistor 74, a power source 76 and a switch 78. It is to be appreciated that the shower head 56 is positioned parallel to and above the heating holder 54, and both the heating holder 54 and the shower head 56 are composed of conductive materials, such as metals. Consequently, the heating holder 54 and the shower head 56 form a capacitor 80 while being charged or discharged. In addition, the capacitor 80 and the resistor 74 of the CVD apparatus 50 are connected in series, and therefore form an RC circuit. As described previously, particles tend to adhere to the surface of the shower head 56, and cause the reaction chamber condition shift. A reaction chamber condition shift not only leads to instable concentration and flux of the reaction gases, but also causes capacitance variations of the capacitor 80. The reaction chamber condition detector 72 charges and discharges the capacitor 80 according to this characteristic, and therefore can detect the reaction chamber condition.

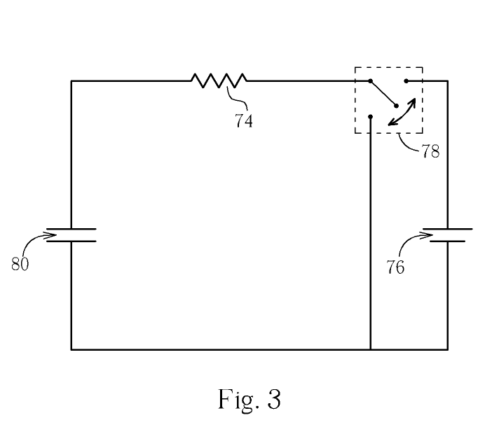

Please refer to FIG. 3, which is an equivalent circuit diagram of the CVD apparatus 50 shown in FIG. 2. As shown in FIG. 3, the resistor 74, the power source 76, the switch 78, and the capacitor 80 form an RC circuit. The switch 78 can be alternatively switched to a charging mode or a discharging mode. In the charging mode, the capacitor 80 begins to be charged. On the contrary, the capacitor 80 is discharged in the discharging mode.

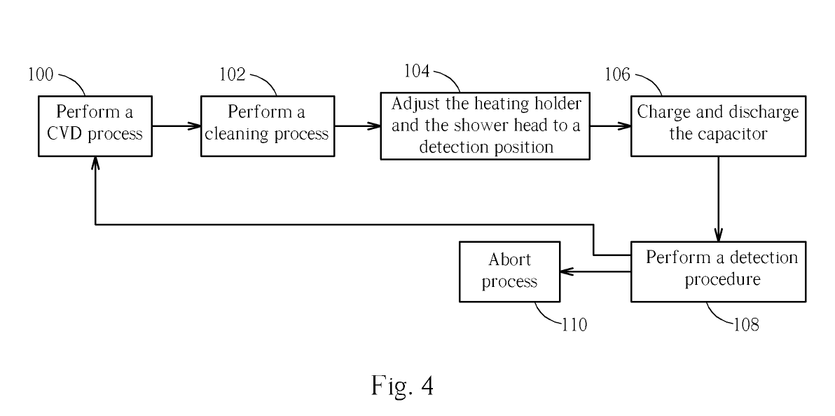

The present invention also provides a method of detecting a reaction chamber condition of a CVD apparatus. Please refer to FIG. 4, which is a flowchart of the method of detecting a reaction chamber condition of a CVD apparatus according to the present invention. As shown in FIG. 4, the method includes the following steps:

Step 100: load a wafer into the reaction chamber, and perform a CVD process;

Step 102: load out the wafer, and perform a cleaning process;

Step 104: adjust the heating holder and the shower head to a detection position, and maintain the reaction chamber in a vacuum condition;

Step 106: utilize the reaction chamber condition detector to charge and discharge the capacitor;

Step 108: calculate a detected value, and perform a detection procedure to compare the detected value with an ideal value, if the detected value substantially equals the ideal value, the reaction chamber condition is normal and step 100 is repeated. If the detected value differs from the ideal value, the reaction chamber condition is shifted and step 110 is executed; and

Step 110: abort process.

According to the method of the present invention, a cleaning process is carried out by implanting gases for cleaning into the reaction chamber subsequent to a CVD process. However, since the particles are not easily completely removed, a detection procedure is followed to detect the reaction chamber condition. First, the heating holder and the shower head are adjusted to a detection position, and the reaction chamber condition detector charges and discharges the capacitor in a vacuum condition so as to calculate a detected value. Subsequently, the detected value is compared with an ideal value. If the detected value equals the ideal value, the reaction chamber condition is normal, and the heating holder and the shower head are returned to a reaction position. If the detected value differs from the ideal value, the reaction chamber condition is shifted and the process is aborted. The charging/discharging theorem and the calculation of the detected value are detailed as follows.

In the course of charging the capacitor, the relationship of the capacitance and the charging time is expressed as equation (a):

$$Vc = ɛ ( 1 - {ⅇ}^{\frac{- t}{RC}} ) \qquad ( a )$$

where t denotes a charging time, R denotes a resistance of the resistor, C denotes a capacitance of the capacitor, and ε denotes a permittivity.

Equation (b) is obtained by rearranging equation (a):

$$ɛ - Vc = ɛ \cdot {ⅇ}^{\frac{- t}{RC}} \qquad ( b )$$

Equation (c) is derived from taking a logarithm of equation (b):

$$t = \frac{RC}{0.434} log [ \frac{ɛ}{ɛ - Vc} ] \qquad ( c )$$

It can be seen from equation (c) that, theoretically, the relationship of t and

$$log [ \frac{ɛ}{ɛ - Vc} ]$$

is linear. Accordingly, a plurality of data points

$$( t , log [ \frac{ɛ}{ɛ - Vc} ] )$$

can be measured, and the least squares method can be employed to obtain a linear equation. Consequently, the slope of the linear equation is

$$\frac{RC}{0.434} .$$

Since R is known, a detected capacitance is calculated.

The detected capacitance represents the current reaction chamber condition. Since an ideal capacitance which represents an ideal reaction chamber condition can be calculated in the same manner, the current reaction chamber condition can be detected by comparing the detected capacitance with the ideal capacitance. It is to be appreciated that the reaction chamber condition can also be detected by directly comparing the slope of the equation derived from the plurality of data points

$$( t , log [ \frac{ɛ}{ɛ - Vc} ] )$$

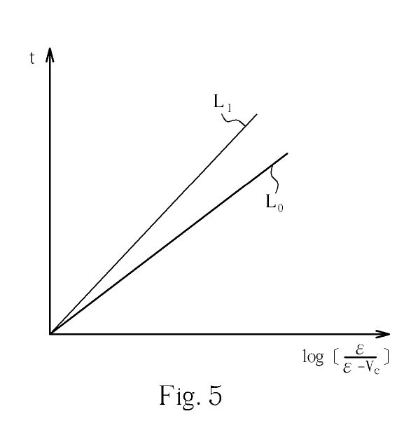

with the slope of the equation that represents the ideal reaction chamber condition. Please refer to FIG. 5, which is a graph of t and

$$log [ \frac{ɛ}{ɛ - Vc} ] .$$

As shown in FIG. 5, L₀ is a straight line which represents an ideal reaction chamber condition, and L₁ is a straight line derived from the plurality of data points

$$( t , log [ \frac{ɛ}{ɛ - Vc} ] ) .$$

Since the slope of L₁ is different from the slope of L₀, the reaction chamber condition is shifted.

In addition to charging the capacitor, the reaction chamber condition can also be detected by discharging the capacitor in the same manner. In the course of discharging the capacitor, the relationship of the capacitance and the discharging time is expressed as equation (d):

$$Vc = ɛ \cdot {ⅇ}^{\frac{- t}{RC}} \qquad ( d )$$

where t denotes a discharging time, R denotes a resistance of the resistor, C denotes a capacitance of the capacitor, and ε denotes a permittivity.

Equation (e) is derived from taking a logarithm of equation (d):

$$t = \frac{RC}{0.434} log [ \frac{ɛ}{Vc} ] \qquad ( e )$$

It can be seen from equation (e) that, theoretically, the relationship of t and

$$log [ \frac{ɛ}{Vc} ]$$

is linear. Accordingly, a plurality of data points

$$( t , log [ \frac{ɛ}{Vc} ] )$$

can be measured, and the least squares method is employed to obtain a linear equation. Consequently, the slope of the linear equation is

$$\frac{RC}{0.434} .$$

Since R is known, a detected capacitance is calculated.

The detected capacitance represents the current reaction chamber condition. Since an ideal capacitance which represents an ideal reaction chamber condition can be calculated, the current reaction chamber condition can be detected by comparing the detected capacitance with the ideal capacitance. It is to be appreciated that the reaction chamber condition can also be detected by comparing the slope of the equation derived from the plurality of data points

$$( t , log [ \frac{ɛ}{Vc} ] )$$

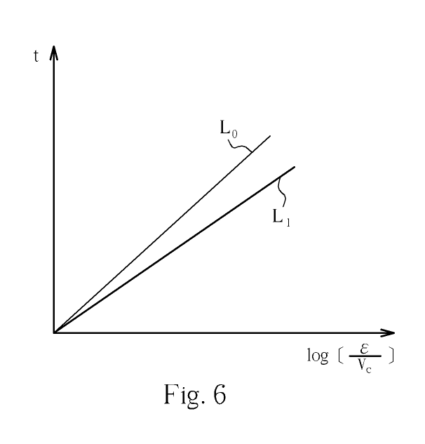

with the slope of the equation that represents the ideal reaction chamber condition. Please refer to FIG. 6, which is a graph of t and

$$log [ \frac{ɛ}{Vc} ] .$$

As shown in FIG. 6, L₀ is a straight line which represents an ideal reaction chamber condition, and L₁ is a straight line derived from the plurality of data points

$$( t , log [ \frac{ɛ}{Vc} ] ) .$$

Since the slope of L₁ is different from the slope of L₀, the reaction chamber condition is shifted.

In comparison with the prior art, since the reaction chamber condition influences the capacitance of the capacitor formed by the heating holder and the shower head, the present invention is capable of detecting the reaction chamber condition by detecting capacitance variations of this capacitor. Consequently, the yield of the CVD process is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of detecting a reaction chamber condition of a chemical vapor deposition apparatus; the chemical vapor deposition apparatus comprising a heating holder positioned in a reaction chamber; a shower head positioned substantially parallel to and above the heating holder in the reaction chamber, the heating holder and the shower head forming a capacitor; and a reaction chamber condition detector, electrically connected to the heating holder and the shower head, comprising a resistor connected to the capacitor in series so as to form an RC circuit; the method comprising:
(a) adjusting the heating holder and the shower head to a detection position;
(b) utilizing the reaction chamber condition detector to charge and to discharge the capacitor, and calculating a detected value; and
(c) comparing the detected value and an ideal value, if the detected value substantially equals to the ideal value, a reaction chamber condition is normal, if the detected value differs from the ideal value, the reaction chamber condition is shifted.

2. The method of claim 1, wherein step (b) is performed in a vacuum condition.

3. The method of claim 1, wherein the detected value is obtained while charging the capacitor.

4. The method of claim 3, wherein the detected value is a capacitance.

5. The method of claim 3, wherein the detected value is a slope of a linear equation
$$t = \frac{RC}{0.434} log [ \frac{ɛ}{ɛ - Vc} ]$$
obtained by charging the capacitor, and the reaction chamber condition is determined by comparing the slope with an ideal slope, wherein t denotes a charging time, R denotes a resistance of the resistor, C denotes a capacitance of the capacitor, and ε denotes a permittivity.

6. The method of claim 1, wherein the detected value is obtained while discharging the capacitor.

7. The method of claim 6, wherein the detected value is a capacitance.

8. The method of claim 6, wherein the detected value is a slope of a linear equation
$$t = \frac{RC}{0.434} log [ \frac{ɛ}{Vc} ]$$
obtained by discharging the capacitor, and the reaction chamber condition is determined by comparing the slope with an ideal slope, wherein t denotes a discharging time, R denotes a resistance of the resistor, C denotes a capacitance of the capacitor, and ε denotes a permittivity.
